(19) United States
(12) Patent Application Publication
(10) Pub. No.: US 2007/0059910 A1
(43) Pub. Date: Mar. 15, 2007

(54) Semiconductor structure and method for manufacturing the same

(76) Inventors: Zing-Way Pei, Tai Chung City (TW); Peng-Shiu Chen, Hsin Chu City (TW)

Correspondence Address: RABIN & BERDO, P.C.;Suite 500, 1101 14th Street, N.W., Washington, DC, 20005, US

(21) Appl. No.: 11/375,337

(22) Filed: Mar. 15, 2006

(30) Foreign Application Priority Data
Sep. 9, 2005 (TW) 94131102

(51) Int. Cl. H01L 21/3205; H01L 21/31; H01L 21/336; H01L 21/4763; H01L 21/8242

(52) U.S. Cl. 438/591; 438/287; 438/240; 438/785

(57) ABSTRACT

A semiconductor structure and method for manufacturing the same is disclosed. The present invention relates to a semiconductor having a dielectric layer applied on a gate of a transistor, and a high dielectric-coefficient, and a manufacturing method of the semiconductor. Ti is formed on HfO₂ to absorb oxygen from the dielectric layer to reduce its thickness, and even make it disappear. However, the TiO₂ grown on the layer of Ti advances the growing of HfO₂. Simultaneously, the dielectric constant of TiO₂ is about 50. The TiO₂ substantially enhances the dielectric constant for the dielectric layer. Ti absorbs the oxygen to reduce its thickness and increase the dielectric constant to reduce EOT. Moreover, TiO₂ is formed and the dielectric constant is increased after heating. Accordingly, leakage is avoided in the TiO₂. The present invention enhances the applications for high-k gate dielectrics with high electric constants, and continuously reduces the EOT.

### BACKGROUND OF THE INVENTION

1. Field of the Invention

The present invention relates to a semiconductor structure and a method for manufacturing the same, and particularly relates to a semiconductor having a dielectric layer applied on a gate of a transistor, and a high dielectric-coefficient, and a manufacturing method for the semiconductor.

2. Description of the Related Art

In the semiconductor process, the function of dielectric layer is to act as an insulating material, such as SiO2 or SiN, for insulating from electrical signals between a conducting layer and a conducting wire. Moreover, it is know that the dielectric layers such as HfO and SiₓNₓ are going to be applied to transistor gates in the future. Hence an atomic layer deposition method will be the main technology used to form a dielectric thin film. However, although forming SiₓNₓ increases the stability of the dielectric thin film structure, the dielectric constant k is decreased. Moreover, in the atomic layer deposition technology, high quality HfSiO needs to be grown in an environment that is full of oxygen. In other words, HfSiO needs to be grown on an oxide layer. Furthermore, when the thickness of the oxide layer is about 5˜10 Å, it becomes an impediment to achieving high dielectric constants and low EOTs (Equivalent Oxide Thickness). Hence, it is vital for micro transistor technology that the thickness of the dielectric layer is reduced in the future.

In The Journal of Applied Physics Hyoung Kim et al published “Engineering chemically abrupt high-k metal oxide/Silicon interfaces using an oxygen-gettering metal overlayer” (Vol. 96 No. 6, page 3467-3472, 2004). The article discussed a Ti layer with HfO2 grown on it to absorb oxygen atoms for removing a dielectric layer. However, when the Ti:O is removed, the HfO₂ will be damaged in the removal process. Moreover, the Ti layer is formed on the HfO2 by PVD (Physical Vapor Deposition). Hence the HfO2 film will be harmed by the high power particles produced from the PVD. Furthermore, because there is a predetermined distance between the Ti layer and the HfO₂ layer, the absorbing efficiency of the Ti layer is decreased when the Ti layer absorbs the oxygen atoms.

### SUMMARY OF THE INVENTION

The present invention provides a semiconductor structure and method for manufacturing the same. The semiconductor structure reduces the thickness of a dielectric layer thereof. Moreover, the present invention is adapted to a future transistor manufacturing process, and can certainly integrate PMOS together with NMOS.

In order to achieve the above objects, a semiconductor structure and a method for manufacturing the same is disclosed. Particularly, the present invention relates to a semiconductor having a dielectric layer applied on a gate of a transistor, and a high dielectric-coefficient, and a manufacturing method for the semiconductor. Ti is formed on the HfO₂ for absorbing oxygen atoms from the dielectric layer so as to reduce its thickness, and even to a point where it disappears completely. However, any TiO₂ grown on the layer of the Ti can advance the growing of the following HfO₂. Simultaneously, the dielectric constant of TiO₂ is about 50, which enhances the dielectric constant for the dielectric layer of the gate substantially. In conclusion, Ti is used to absorb the oxygen atoms so as to reduce their thickness and increase the dielectric constant, and to further reduce EOT. Moreover, TiO₂ is formed and the dielectric constant is increased as well after a heating process. Accordingly, leakage can be avoided in the TiO₂. Consequently, the present invention enhances the application of high-k gate dielectric with high electric constant, and continuously reduces the EOT.

A first aspect of the present invention is a semiconductor structure. The semiconductor structure comprises a substrate, a dielectric layer unit and a conducting layer. The dielectric layer unit is formed on the substrate, and the dielectric layer includes at least a metal oxide layer and a metal layer stacked on each other. The conducting layer is formed on the dielectric layer unit.

A second aspect of the present invention is a method for manufacturing a semiconductor structure. The method comprises: providing a substrate; forming a dielectric layer unit on the substrate, wherein the dielectric layer includes at least a metal oxide layer and a metal layer stacked on each other; and forming a conducting layer on the dielectric layer unit.

Moreover, in the first and second aspects, the metal oxide layer comprises at least a first metal oxide layer and a second metal oxide layer. The metal layer comprises at least a first metal layer. The first metal layer, the first metal oxide layer and the second metal oxide layer are stacked sequentially to form the dielectric layer unit.

Furthermore, in the first and second aspects, the metal oxide layer comprises at least a first metal oxide layer, a second metal oxide layer and a third metal oxide layer. The metal layer comprises at least a second metal layer. The first metal oxide layer, the second metal layer, the second metal oxide layer and the third metal oxide layer are stacked sequentially to form the dielectric layer unit.

A third aspect of the present invention is a method for manufacturing a semiconductor structure. The method comprises: providing a substrate; forming a chemical oxide layer on the substrate; forming a first metal oxide layer on the chemical oxide layer; forming a first metal layer on the first metal oxide layer; forming a second metal layer on the first metal layer; forming a second metal oxide layer on the second metal layer; and forming a conducting layer on the second metal oxide layer.

A fourth aspect of the present invention is a semiconductor structure. The semiconductor structure comprises a substrate, a chemical oxide layer formed on the substrate, a first metal oxide layer formed on the chemical oxide layer, a first metal layer formed on the first metal oxide layer, a second metal layer formed on the first metal layer, a second metal oxide layer formed on the second metal layer, and a conducting layer formed on the second metal oxide layer.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a schematic, cross-sectional view of a semiconductor structure according to the first embodiment of the present invention;

FIG. 2 is a schematic, cross-sectional view of a semiconductor structure according to the second embodiment of the present invention;

FIG. 3 is a schematic, cross-sectional view of a semiconductor structure according to the third embodiment of the present invention;

FIG. 4 is a schematic, cross-sectional view of a semiconductor structure according to the fourth embodiment of the present invention;

FIG. 5 is a flowchart of a method for manufacturing a semiconductor structure according to the first embodiment of the present invention;

FIG. 6 is a flowchart of a method for manufacturing a semiconductor structure according to the second embodiment of the present invention;

FIG. 7 is a flowchart of a method for manufacturing a semiconductor structure according to the third embodiment of the present invention; and

FIG. 8 is a flowchart of a method for manufacturing a semiconductor structure according to the fourth embodiment of the present invention.

### DETAILED DESCRIPTION OF PREFERRED EMBODIMENTS

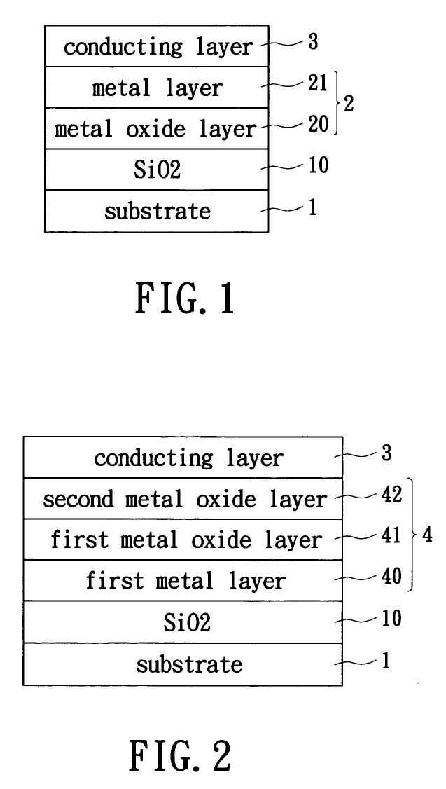

FIG. 1 shows a schematic, cross-sectional view of a semiconductor structure according to the first embodiment of the present invention. The present invention provides a semiconductor structure, comprising a substrate 1, a dielectric layer unit 2 and a conducting layer 3.

The substrate 1 can be a Si substrate that has a SiO₂ formed thereon. The dielectric layer unit 2 is formed on the substrate 1, and the dielectric layer 2 includes at least a metal oxide layer 20 and a metal layer 21 stacked upon each other. The conducting layer 3 is formed on the dielectric layer unit 2, and the conducting layer 3 can be TiN.

Moreover, the metal oxide layer 20 can be HfO₂, HfSiO, HfSiON or TiO₂. The thickness of both the HfO₂ and the HfSiO can be between 0.1˜3 nm or 0.1˜5 nm, the thickness of the HfSiON can be between 0.1˜3 nm, and the thickness of the TiO₂ can be between 0.1˜2 nm. The metal layer 21 can be Ti, and the thickness of the Ti can be between 0.1˜2 nm. However, both the thickness and material of the metal oxide layer or the metal layer should not be used to limit the present invention.

FIG. 2 shows a schematic, cross-sectional view of a semiconductor structure according to the second embodiment of the present invention. The present invention provides a semiconductor structure, comprising a substrate 1, a dielectric layer unit 4, and a conducting layer 3.

The second embodiment differs from the first embodiment in that the dielectric layer unit 4 has a first metal layer 40, a first metal oxide layer 41, and a second metal oxide layer 42 stacked sequentially. The first metal layer 40 can be Ti, and the thickness of the Ti is between 0.1˜2 nm. Both the first metal oxide layer 41 and the second metal oxide layer 42 can be HfO₂, HfSiO, HfSiON, or TiO₂. The thickness of the HfO₂, HfSiO, HfSiON, or TiO₂ are all between 0.1˜3 nm or 0.1˜5 nm. Moreover, the total thickness of both the first metal layer and the first metal oxide layer can be between 0.1˜2 nm. However, both the thickness and material of the metal oxide layer or the metal layer should not be used to limit the present invention.

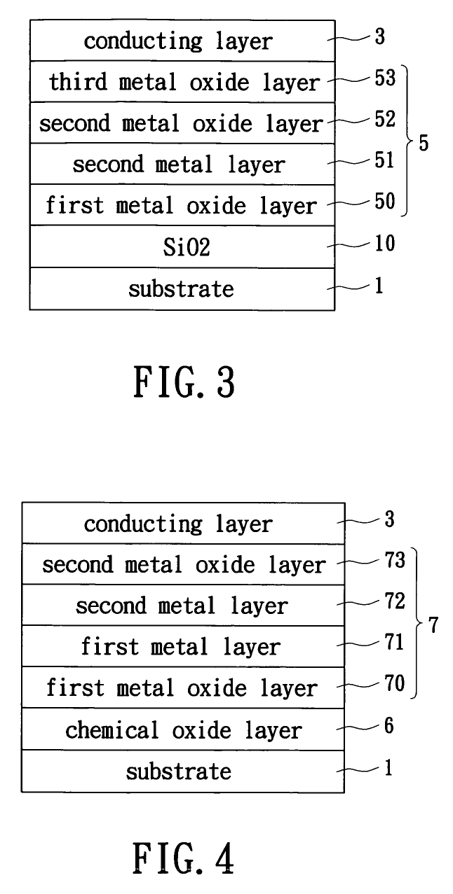

FIG. 3 shows a schematic, cross-sectional view of a semiconductor structure according to the third embodiment of the present invention. The present invention provides a semiconductor structure, comprising a substrate 1, a dielectric layer unit 5, and a conducting layer 3.

The third embodiment differs from the first and second embodiments in that the dielectric layer unit 5 has a first metal oxide layer 50, a second metal layer 51, a second metal oxide layer 52, and a third metal oxide layer 53 stacked sequentially. The second metal layer can be Ti, and the thickness of the second metal layer can be between 0.1˜2 nm. The first metal oxide layer 50 can be HfO₂, HfSiO or HfSiON, and the thickness of the first metal oxide layer 50 can be between 0.1˜3 nm or 0.1˜5 nm. The second metal oxide layer 52 can be TiO₂. The third metal oxide layer 53 can be HfO₂, HfSiO or HfSiON, and the thickness of the first metal oxide layer 53 can be between 0.1˜3 nm or 0.1˜5 nm. However, both the thickness and material of the metal oxide layer or the metal layer should not be used to limit the present invention.

FIG. 4 shows a schematic, cross-sectional view of a semiconductor structure according to the fourth embodiment of the present invention. The present invention provides a semiconductor structure comprising a substrate 1, a chemical oxide layer 6, a first metal oxide layer 70, a first metal layer 71, a second metal layer 72, a second metal oxide layer 73, and a conducting layer 3.

The chemical oxide layer 6 is formed on the substrate 1. The first metal oxide layer 70 is formed on the chemical oxide layer 6. The first metal layer 71 is formed on the first metal oxide layer 70. The second metal layer 72 is formed on the first metal layer 71. The second metal oxide layer 73 is formed on the second metal layer 72. The conducting layer 3 is formed on the second metal oxide layer 73. Hence the first metal oxide layer 70, the first metal layer 71, the second metal layer 72, and the second metal oxide layer 73 can be stacked sequentially to form a dielectric layer unit 7.

Moreover, both the first metal oxide layer 70 and the second metal oxide layer 73 can be HfO₂, HfSiO, HfSiON, or TiO₂, and their thickness can be between 0.1˜3 nm or 0.1˜5 nm. Both the first metal layer 71 and the second metal layer 72 can be Ti, and its thickness can be between 0.1˜2 nm. Furthermore, as in the first embodiment, the substrate 1 can be a Si substrate that has a SiO₂ formed thereon.

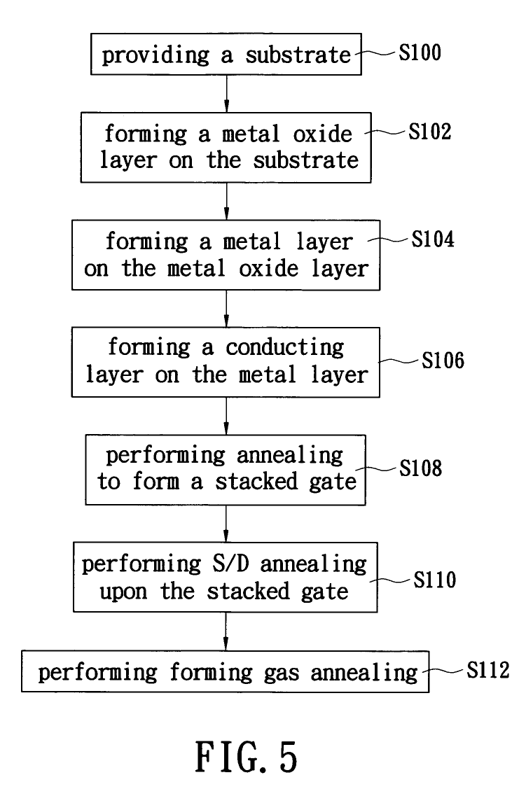

FIG. 5 shows a flowchart of a method for manufacturing a semiconductor structure according to the first embodiment of the present invention. The present invention provides a method for manufacturing a semiconductor structure, comprising: providing a substrate 1 (S100); forming a metal oxide layer 20 on the substrate 1 (S102); and forming a metal layer 21 on the metal oxide layer 20 (S104). Hence the metal oxide layer 20 and the metal layer 21 are stacked upon each other to form a dielectric layer unit 2. Next, the method comprises forming a conducting layer 3 on the metal layer 21 (S106). Moreover, both the dielectric layer unit 2 and the conducting layer 3 are formed by a LTCVD (Low Temperature Chemical Vapor Deposition) that is an ALD (Atomic Layer Deposition) device.

Furthermore, after the step S106, the method further comprises: performing annealing to form a stacked gate (S108); performing S/D (Source/Drain) annealing upon the stacked gate (S110); and performing forming gas annealing (S112). In addition, during the step S110 and the step S112, oxygen is doped into Ti to from TiO₂.

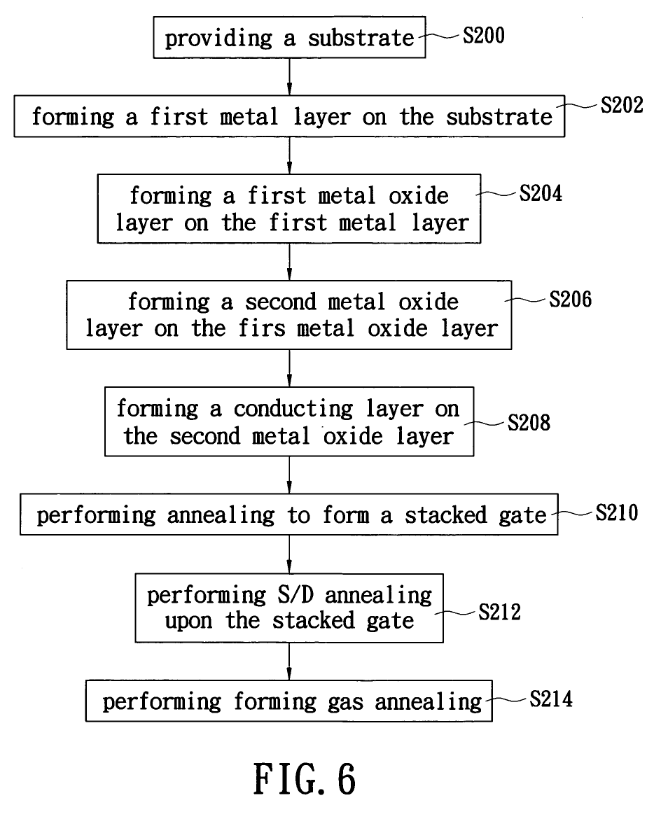

FIG. 6 shows a flowchart of a method for manufacturing a semiconductor structure according to the second embodiment of the present invention. The present invention provides a method for manufacturing a semiconductor structure, comprising: providing a substrate 1 (S200); forming a first metal layer 40 on the substrate 1 (S202); forming a first metal oxide layer 41 on the first metal layer 40 (S204); and forming a second metal oxide layer 42 on the first metal oxide layer 41 (S206). Hence the first metal layer 40, the first metal oxide layer 41 and the second metal oxide layer 42 are stacked sequentially to form the dielectric layer unit 4. Next, the method comprises forming a conducting layer 3 on the second metal oxide layer 42 (S208). Moreover, both the dielectric layer unit 4 and the conducting layer 3 are formed by a LTCVD (Low Temperature Chemical Vapor Deposition) that is an ALD (Atomic Layer Deposition) device.

Furthermore, after the step S208, the method further comprises: performing annealing to form a stacked gate (S210); performing S/D (Source/Drain) annealing upon the stacked gate (S212); and performing forming gas annealing (S214). In addition, during the step S212 and the step S214, oxygen is doped into Ti to from TiO₂.

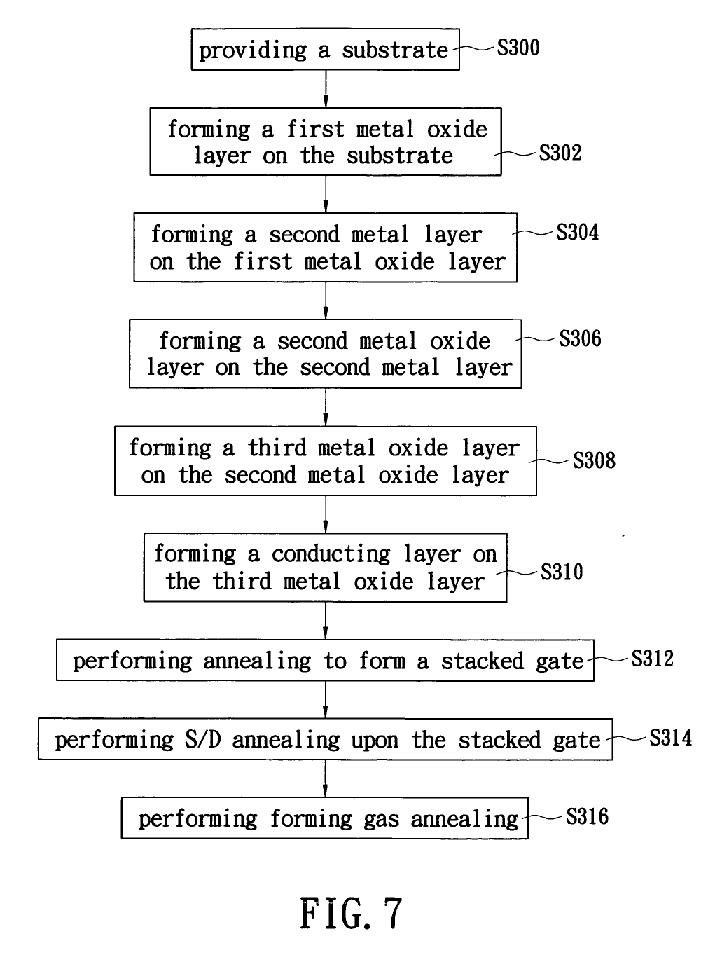

FIG. 7 shows a flowchart of a method for manufacturing a semiconductor structure according to the third embodiment of the present invention. The present invention provides a method for manufacturing a semiconductor structure, comprising: providing a substrate 1 (S300); forming a first metal oxide layer 50 on the substrate 1 (S302); forming a second metal layer 51 on the first metal oxide layer 50 (S304); forming a second metal oxide layer 52 on the second metal layer 51 (S306); and forming a third metal oxide layer 53 on the second metal oxide layer 52 (S308). Hence the first metal oxide layer 50, the second metal layer 51, the second metal oxide layer 52 and the third metal oxide layer 53 are stacked sequentially to form the dielectric layer unit 5. Next, the method comprises forming a conducting layer 3 on the third metal oxide layer 53 (S310). Moreover, both the dielectric layer unit 5 and the conducting layer 3 are formed by a LTCVD (Low Temperature Chemical Vapor Deposition) that is an ALD (Atomic Layer Deposition) device.

Furthermore, after the step S310, the method further comprises: performing annealing to form a stacked gate (S312); performing S/D (Source/Drain) annealing upon the stacked gate (S314); and performing forming gas annealing (S316). In addition, during the step S314 and the step S316, oxygen is doped into Ti to from TiO₂.

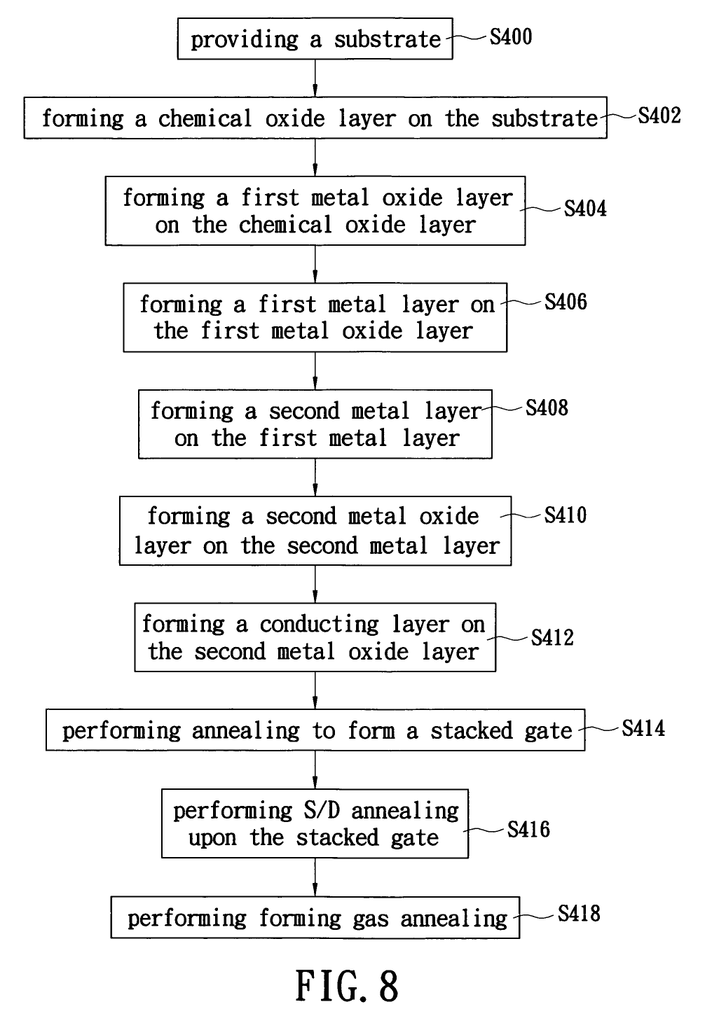

FIG. 8 shows a flowchart of a method for manufacturing a semiconductor structure according to the fourth embodiment of the present invention. The present invention provides a method for manufacturing a semiconductor structure, comprising: providing a substrate 1 (S400); forming a chemical oxide layer 6 on the substrate 1 (S402); forming a first metal oxide layer 70 on the chemical oxide layer 6 (S404); forming a first metal layer 71 on the first metal oxide layer 70 (S406); forming a second metal layer 72 on the first metal layer 71 (S408); and forming a second metal oxide layer 73 on the second metal layer 72 (S410). Hence, the first metal oxide layer 70, the first metal layer 71, the second metal layer 72 and the second metal oxide layer 73 are stacked sequentially to form the dielectric layer unit 7. Next, the method comprises forming a conducting layer 3 on the second metal oxide layer 73 (S412). Moreover, both the dielectric layer unit 7 and the conducting layer 3 are formed by a LTCVD (Low Temperature Chemical Vapor Deposition) that is an ALD (Atomic Layer Deposition) device.

Furthermore, after the step S412, the method further comprises: performing annealing to form a stacked gate (S414); performing S/D (Source/Drain) annealing upon the stacked gate (S416); and performing forming gas annealing (S418). In addition, during the step S416 and the step S418, oxygen is doped into Ti to from TiO₂.

To sum up, the present invention forms Ti on the HfO₂ absorb oxygen atoms from the dielectric layer so as to reduce its thickness, and even make it disappear. However, the TiO₂ that is grown on the layer of Ti can advance the growing of the following HfO₂. Simultaneously, the dielectric constant of TiO₂ is about 50, so it enhances the dielectric constant for the dielectric layer of the gate substantially. In conclusion, Ti is used to absorb the oxygen atoms so as to reduce its thickness and increase dielectric constant, and to reduce EOT further. Moreover, TiO₂ is formed and the dielectric constant is increased as well after a heating process. Accordingly, leakage can be avoided in the TiO₂. Consequently, the present invention enhances the application for the high-k gate dielectric with a high electric constant, and continuously reduces the EOT.

Furthermore, compared with the example presented by Hyoung Kim et al., the present invention effectively reduces the damage caused by the HfO₂ by using a CVD method to perform a continuous coating process. In addition, the present invention's Ti layer is formed on the HfO₂ layer, and the Ti layer is close to an oxide layer to increase the efficiency of the Ti to absorb the oxygen atoms. Moreover, the Ti layer is doped into the dielectric layer. Hence, after the Ti layer absorbs the oxygen atom, it can be changed to TiO₂ so as to increase the dielectric constant k and reduce EOT.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A semiconductor structure, comprising:
a substrate;
a dielectric layer unit formed on the substrate, and the dielectric layer at least including a metal oxide layer and a metal layer stacked upon each other; and
a conducting layer formed on the dielectric layer unit.

2. The semiconductor structure as claimed in claim 1, wherein the conducting layer is TiN.

3. The semiconductor structure as claimed in claim 1, wherein the metal oxide layer is HfO₂, HfSiO, HfSiON, or TiO₂.

4. The semiconductor structure as claimed in claim 1, wherein the metal layer is Ti.

5. The semiconductor structure as claimed in claim 1, wherein the thickness of the metal oxide layer is between 0.1˜5 nm.

6. The semiconductor structure as claimed in claim 1, wherein the thickness of the metal layer is between 0.1˜2 nm.

7. The semiconductor structure as claimed in claim 1, wherein the metal oxide layer comprises at least a first metal oxide layer and a second metal oxide layer, the metal layer comprises at least a first metal layer, and the first metal layer, the first metal oxide layer and the second metal oxide layer are stacked sequentially to form the dielectric layer unit.

8. The semiconductor structure as claimed in claim 7, wherein the first metal layer is Ti, the first metal oxide layer is TiO₂, and the total thickness of both the first metal layer and the first metal oxide layer is between 0.1˜2 nm.

9. The semiconductor structure as claimed in claim 7, wherein the second metal oxide layer is HfO₂, HfSiO or HfSiON, and the thickness of the second metal oxide is between 0.1˜5 nm.

10. The semiconductor structure as claimed in claim 1, wherein the metal oxide layer comprises at least a first metal oxide layer, a second metal oxide layer and a third metal oxide layer, the metal layer comprises at least a second metal layer, and the first metal oxide layer, the second metal layer, the second metal oxide layer and the third metal oxide layer are stacked sequentially to form the dielectric layer unit.

11. The semiconductor structure as claimed in claim 10, wherein the second metal layer is Ti, and the thickness of the second metal layer is between 0.1˜2 nm.

12. The semiconductor structure as claimed in claim 10, wherein the first metal oxide layer is HfO₂, HfSiO, or HfSiON, and the thickness of the first metal oxide layer is between 0.1˜3 nm or 0.1˜5 nm.

13. The semiconductor structure as claimed in claim 10, wherein the second metal oxide layer is TiO₂.

14. The semiconductor structure as claimed in claim 10, wherein the third metal oxide layer is HfO₂, HfSiO, or HfSiON, and the thickness of the first metal oxide layer is between 0.1˜3 nm or 0.1˜5 nm.

15. The semiconductor structure as claimed in claim 1, wherein both the dielectric layer unit and the conducting layer are formed by a LTCVD (Low Temperature Chemical Vapor Deposition) that is an ALD (Atomic Layer Deposition) device.

16. A method for manufacturing a semiconductor structure, comprising:
providing a substrate;
forming a dielectric layer unit on the substrate, wherein the dielectric layer includes at least a metal oxide layer and a metal layer stacked upon each other; and
forming a conducting layer on the dielectric layer unit.

17. The method as claimed in claim 16, wherein the conducting layer is TiN.

18. The method as claimed in claim 16, wherein the metal oxide layer is HfO₂, HfSiO, HfSiON, or TiO₂, and the thickness of the metal oxide is between 0.1˜5 nm.

19. The method as claimed in claim 16, wherein the metal layer is Ti.

20. The method as claimed in claim 16, wherein the thickness of the metal layer is between 0.1˜2 nm.

21. The method as claimed in claim 16, wherein both the dielectric layer unit and the conducting layer are formed by a LTCVD (Low Temperature Chemical Vapor Deposition) that is an ALD (Atomic Layer Deposition) device.

22. The method as claimed in claim 16, wherein after forming the conducting layer step further comprises:
performing annealing to form a stacked gate;
performing S/D (Source/Drain) annealing upon the stacked gate; and
performing forming gas annealing;
wherein oxygen is doped into Ti to from TiO₂ during the performing S/D annealing step and the performing forming gas annealing step.

23. The method as claimed in claim 16, wherein the metal oxide layer comprises at least a first metal oxide layer and a second metal oxide layer, the metal layer comprises at least a first metal layer, and the first metal layer, the first metal oxide layer and the second metal oxide layer are stacked sequentially to form the dielectric layer unit.

24. The method as claimed in claim 16, wherein the metal oxide layer comprises at least a first metal oxide layer, a second metal oxide layer and a third metal oxide layer, the metal layer comprises at least a second metal layer, and the first metal oxide layer, the second metal layer, the second metal oxide layer and the third metal oxide layer are stacked sequentially to form the dielectric layer unit.

25. A method for manufacturing a semiconductor structure, comprising:
providing a substrate;
forming a chemical oxide layer on the substrate;
forming a first metal oxide layer on the chemical oxide layer;
forming a first metal layer on the first metal oxide layer;
forming a second metal layer on the first metal layer;
forming a second metal oxide layer on the second metal layer; and
forming a conducting layer on the second metal oxide layer.

26. The method as claimed in claim 25, wherein both the dielectric layer unit and the conducting layer are formed by a LTCVD (Low Temperature Chemical Vapor Deposition) that is an ALD (Atomic Layer Deposition) device.

27. The method as claimed in claim 25, after forming the conducting layer step, further comprising:
performing annealing to form a stacked gate;
performing S/D (Source/Drain) annealing upon the stacked gate; and
performing forming gas annealing;
wherein oxygen is doped into Ti to from TiO₂ during the performing S/D annealing step and the performing forming gas annealing step.

28. A semiconductor structure, comprising:
a substrate;
a chemical oxide layer formed on the substrate;
a first metal oxide layer formed on the chemical oxide layer;
a first metal layer formed on the first metal oxide layer;
a second metal layer formed on the first metal layer;
a second metal oxide layer formed on the second metal layer; and
a conducting layer formed on the second metal oxide layer.

29. The semiconductor structure as claimed in claim 28, wherein the metal oxide layer is HfO₂, HfSiO, HfSiON, or TiO₂, and the thickness of the metal oxide layer is between 0.1˜5 nm.

30. The semiconductor structure as claimed in claim 1, wherein the metal layer is Ti, and the thickness of the metal layer is between 0.1˜2 nm.
